(19) United States
(12) Patent Application Publication
(10) Pub. No.: US 2013/0120954 A1
(43) Pub. Date: May 16, 2013

(54) Stand for a Plurality of Electronic Devices

(71) Applicant: Jerry Moscovitch, Toronto (CA)

(72) Inventor: Jerry Moscovitch, Toronto (CA)

(21) Appl. No.: 13/731,905

(22) Filed: Dec. 31, 2012

Related U.S. Application Data
(63) Continuation of application No. 12/696,929, filed on Jan. 29, 2010, now abandoned.
(60) Provisional application No. 61/158,945, filed on Mar. 10, 2009.
(60) Provisional application No. 61/245,144, filed on Sep. 23, 2009.

(51) Int. Cl. H05K 7/18

(52) U.S. Cl. CPC H05K 7/18
USPC 361/809

(57) ABSTRACT

A multi-display stand is described having a base structure for supporting N displays. The base structure includes a base, a support column connected to the base, and an extensions receptor connected to the support column. The multi-display stand further includes a first extension removably connected to one end of the extensions receptor, and a second extension removably connected to another end of the extensions receptor. The first extension, the extensions receptor and the second extension together can support N displays, where a) the first extension supports at least one display from among the N displays and the second extension supports at least one other display from among the N displays, and b) the first extension and the second extension can be removed to allow the extensions receptor to support M displays where 0<M<N.

### CROSS REFERENCE TO RELATED APPLICATIONS

This application is a continuation of application Ser. No. 12/696,929 filed on Jan. 29, 2010, which claims priority to provisional application No. 61/158,945, filed Mar. 10, 2009, and provisional application No. 61/245,144, filed Sep. 23, 2009.

### BACKGROUND OF THE INVENTION

The number of multi-monitor or multi-screen computer display systems has increased in recent years as computer users in various industries adapt their use to new environments. For example, a multi-monitor display system can be used to create the illusion of a larger screen, thereby allowing a securities trader to view a large single spreadsheet over several displays. Alternately, the trader may view individual applications on individual screens (for example, one screen may display a Web Browser, a second a new service and a third a spreadsheet of financial data).

Individuals working with still or moving images, such as graphics artists, video or film editors or medical diagnosticians may also use multi-monitor display systems. A given image may be viewed across several screens or two images may be viewed side-by-side (such as two x-ray images used to assess the extent to which a broken bone has healed). Although the potential uses for multi-display systems appear to be limited only by the user's imagination, there are limitations to such devices.

One limitation concerns the large size of multi-monitor display systems. With the number of monitors per display system reaching four, six or even greater, the size of the display system, and the concomitant shipping costs can become large. Therefore, any innovation that can reduce the size of multi-monitor computer systems would be desirable.

### BRIEF SUMMARY OF THE INVENTION

Described herein is a multi-display stand that includes a base structure for supporting N displays. The base structure includes a base, a support column connected to the base, and an extensions receptor connected to the support column. The multi-display stand further includes a first extension removably connected to one end of the extensions receptor. One of the first extension and the extensions receptor includes a first displaceable member having an equilibrium position, and the other one of the first extension and the extensions receptor includes a first displacing member that displaces the first displaceable member when the first extension and the extensions receptor are being connected. The first displaceable member experiences a first restoring force when displaced that tends to return the first displaceable member to the equilibrium position thereof causing the first extension to secure to the extensions receptor when the first displacing member can mate with a notch.

A second extension may also be provided that removably connects to another end of the extensions receptor. One of the second extension and the extensions receptor includes a second displaceable member having an equilibrium position, and the other one of the second extension and the extensions receptor includes a second displacing member that displaces the second displaceable member when the second extension and the extensions receptor are being connected. The second displaceable member experiences a second restoring force when displaced that tends to return the second displaceable member to the equilibrium position thereof causing the second extension to secure to the extensions receptor when the second displacing member can mate with a notch.

The first extension, the extensions receptor and the second extension together can support N displays, where a) the first extension supports at least one display from among the N displays and the second extension supports at least one other display from among the N displays, and b) the first extension and the second extension can be removed to allow the extensions receptor to support M displays where 0<M<N.

Also described herein is a multi-device stand that includes a base structure for supporting a plurality of electronic devices. The base structure includes a base, a support column connected to the base, and an extensions receptor connected to the support column. The multi-device stand further includes an extension removably connected to one end of the extensions receptor. In one embodiment, the extension is adapted to support at least one peripheral device, which although perhaps having an electronic display, is not solely an electronic display, such as a printer or fax machine.

### BRIEF DESCRIPTION OF THE DRAWINGS

FIGS. 1A-E are perspective drawings of a multi-display stand according to the principles of the present invention.

FIG. 2A-B show exploded and perspectives views of the connector of FIGS. 1A-E.

FIG. 2C shows the first extension station of FIGS. 1A-E.

FIG. 2D shows a connector affixed to the station of FIG. 2C.

FIGS. 3A-C are an exploded front view, an exploded back view and an assembled back view of a station near an end of the extensions receptor and the portion of the second extension that connects thereto according to the principles of the present invention.

FIGS. 4A-E are perspective drawings of another embodiment of a multi-display stand according to the principles of the present invention.

FIGS. 5A-E are perspective drawings of another embodiment of a multi-display stand according to the principles of the present invention.

FIGS. 6A-6C are a perspective drawing of a multi-device stand for supporting electronic devices according to the principles of the present invention.

FIG. 7 is a perspective drawing of base structure having a base that includes a clamp according to the principles of the present invention.

FIG. 8 is a perspective drawing of another embodiment of a stand that requires no tools or bolts to removably connect the extensions to the extensions receptor according to the principles of the present invention.

FIGS. 9A-C show cross sections corresponding to section A-A of FIG. 8.

### DETAILED DESCRIPTION OF THE INVENTION

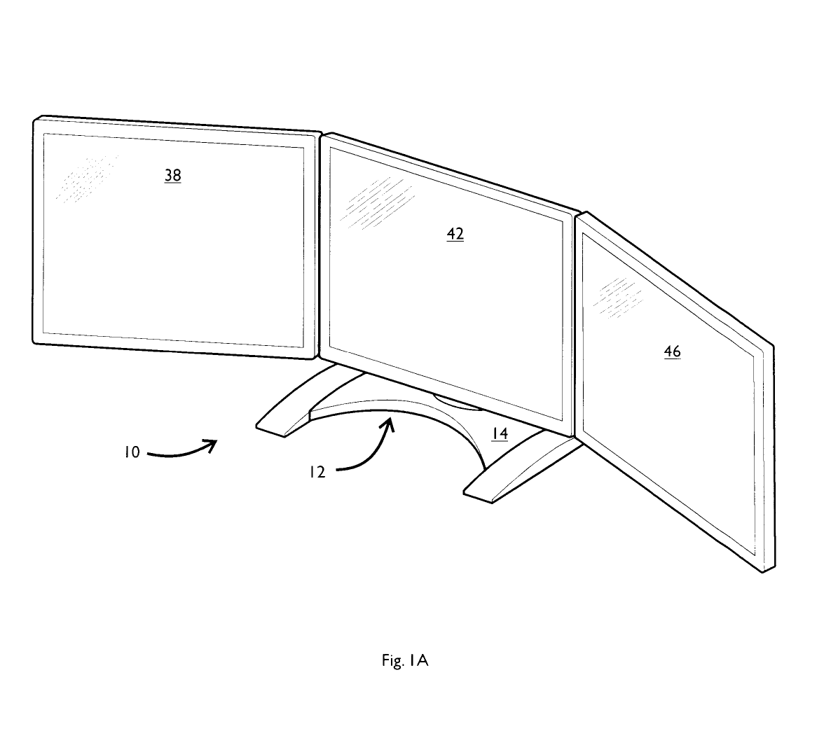

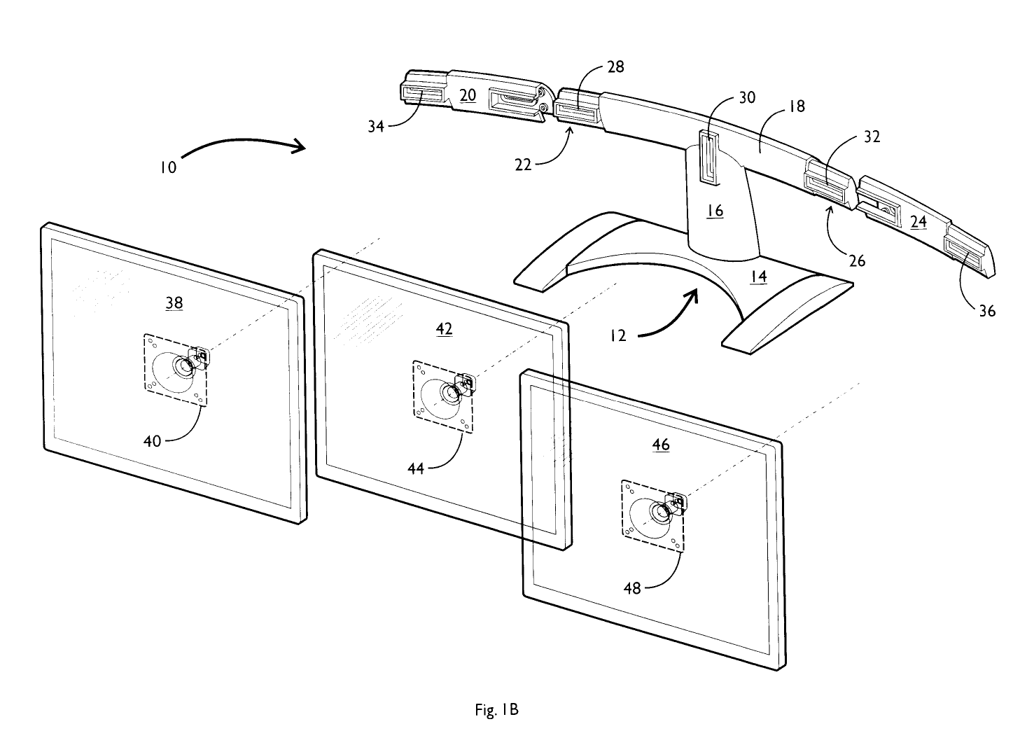

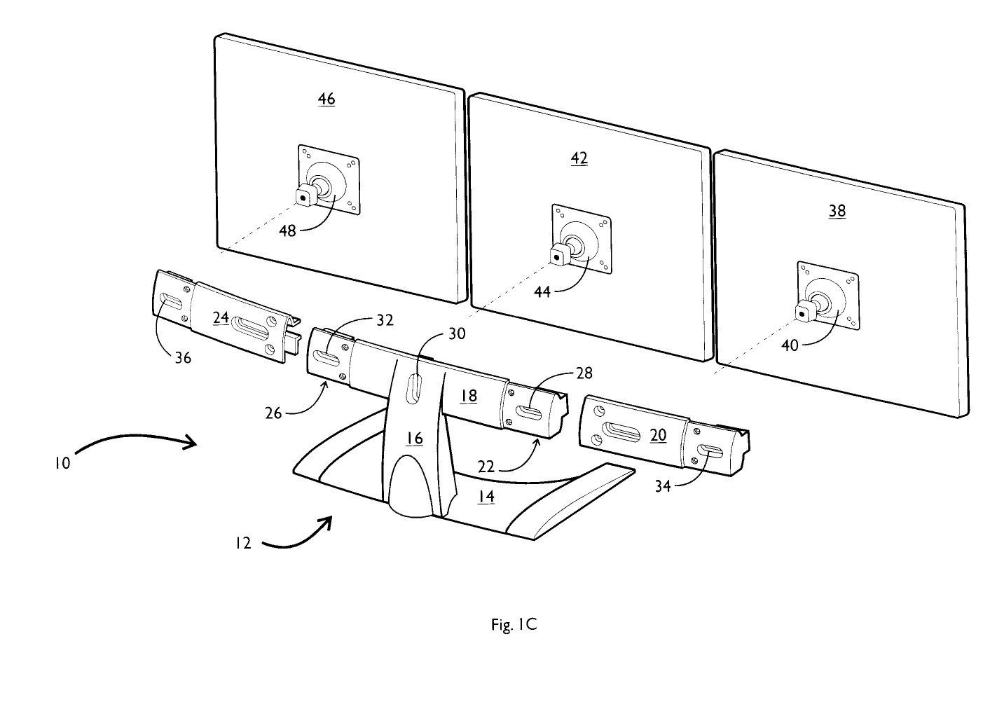

FIGS. 1A-E depict a multi-display stand 10 having a base structure 12, which structure 12 includes a base 14, a support column 16 connected to the base 14, and an extensions receptor 18 connected to the support column 16. In the embodiment of FIGS. 1A-E, the extensions receptor 18 includes an arm extending from either side of the support column 16. The base 14 and the support column 16 can be an integral unit or can consist of a separate base and support column connected together by fastening means, such as screws. Likewise, the support column 16 and the extensions receptor 18 can be an integral unit or can consist of a separate support column 16 and extensions receptor 18 connected together by fastening means, such as screws. Moreover, it should be understood that the extensions receptor 18 can be one integral unit or can be composed of two or more, perhaps separate, subcomponents.

The multi-display stand 10 also includes a first extension 20 removably connected to one end 22 of the extensions receptor 18 and a second extension 24 removably connected to an opposite end 26 of the extensions receptor 18.

The extensions receptor 18 includes a first outer station 28, a central station 30 and a second outer station 32. The first extension 20 includes a first extension station 34 and the second extension 24 includes a second extension station 36.

The back of a first outer display 38 has a first outer connector 40, the back of a central display 42 has a central connector 44 and the back of a second outer display 46 has a second outer connector 48. The connector 40 mates with the first extension station 34, the connector 44 mates with the central station 30 and the connector 48 mates with the second extension station 36. In this manner, the extensions receptor 18 can support the central display 42, the first extension 20 can support the first outer display 42 and the second extension 24 can support the second outer display 46. The connectors 40, 44 and 48 are also capable of mating with some or all of the other stations 28, 30, 32, 34 and 36.

Each of the connectors 40, 44 and 48 can be disconnected from the station mated therewith. Likewise, each extension 20, 24 can be disconnected from the extensions receptor 18. FIG. 1B and FIG. 1C show a front and rear view respectively of the multi-display stand 10, with the three displays 38, 42 and 46 disconnected therefrom, and the two extensions 20 and 24 disconnected from the extensions receptor 18.

The first extension 20 is removably connected to the end 22 of the extensions receptor 18, and the second extension 24 is removably connected to the end 26 of the extensions receptor 18. In FIG. 1B and FIG. 1C, the first extension 20 and the second extension 24 are shown disconnected from the extensions receptor 18. By removing the two extensions 20 and 24, the extensions receptor 18 is allowed to support two displays 50 and 52, which have connectors 51 and 53 at the back. It should be understood that the two displays 50 and 52 can be chosen from among the first outer display 38, the central display 42 and the second outer display 46 provided the connectors at the back of the displays can mate with the appropriate stations on the extensions receptor 18.

In FIG. 1D, a portion of the multi-display stand 10 is shown with the extensions 20 and 24 absent to illustrate how the two displays 50 and 52 mate with the first outer station 28 and the second outer station 32. FIG. 1E shows the two displays 50 and 52 being supported by the extensions receptor 18.

In the embodiment described above, the multi-display stand 10 conveniently allows a three-display system (FIGS. 1A-C) to be converted into a two-display system (FIGS. 1D-E). In particular, the display stand 10 can support three displays 38, 42 and 46 when the extensions 20 and 24 are attached to the extensions receptor 18, and can support two displays 50 and 52 on the extensions receptor 18 when the extensions 20 and 24 are removed therefrom.

More generally, according to the principles of the present invention, a multi-display stand supports N displays, where N is an integer greater than or equal to two. A first extension, removably connected to one end of an extensions receptor, supports at least one display from among the N displays. Likewise, a second extension, removably connected to another end of the extensions receptor, supports at least one other display from among the N displays. The first extension and the second extension can be removed to allow the extensions receptor to support M displays, where M is an integer greater than zero and less than N. In the embodiment of FIGS. 1A-E, N=3 and M=2.

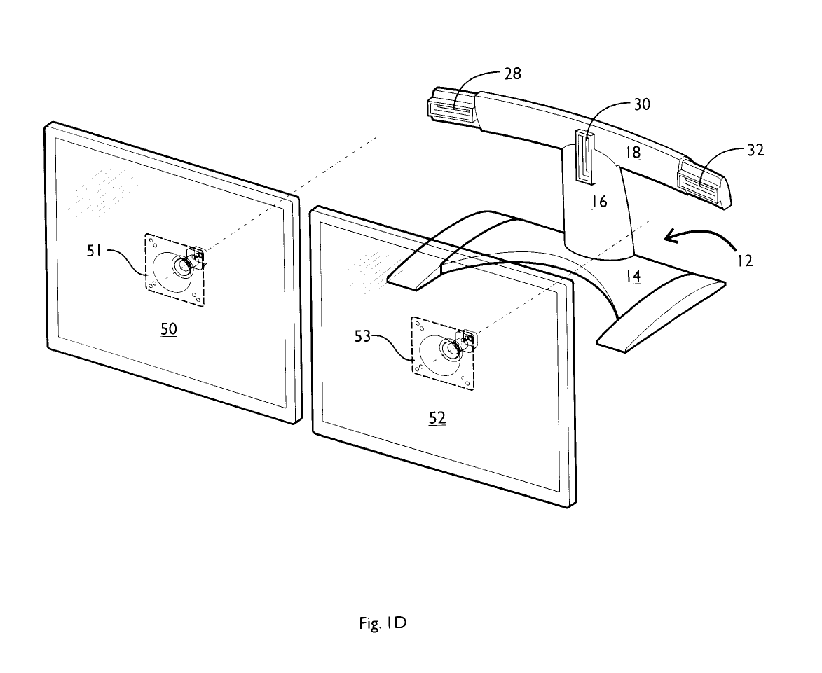

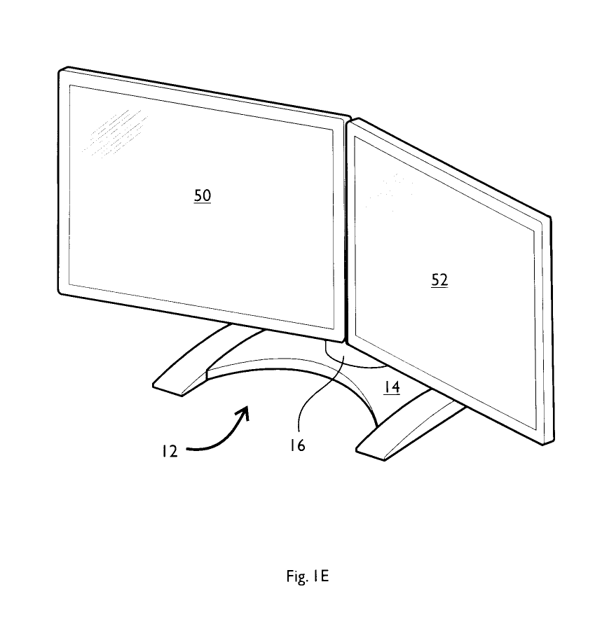

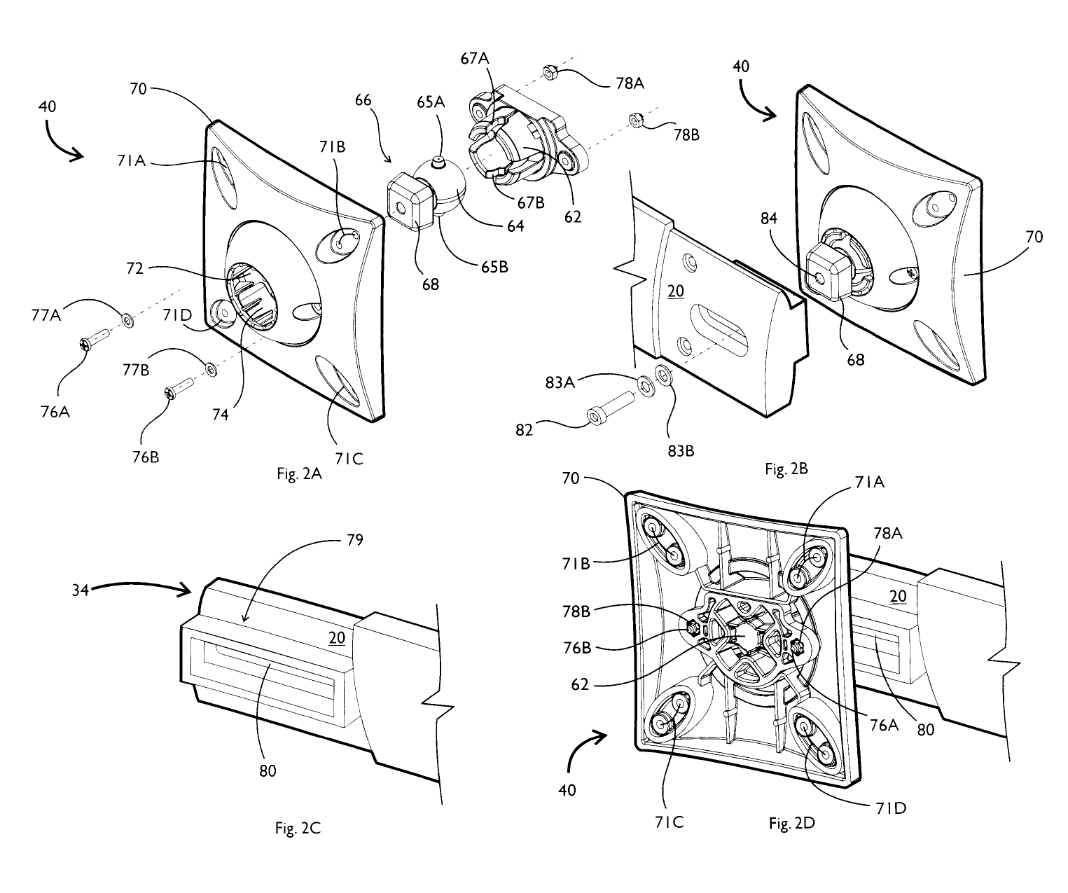

FIGS. 2A (exploded view) and 2B show the connector 40 of FIG. 1. FIG. 2C shows the station 34 and FIG. 2D shows the connector 34 affixed to the station 34. The connector 40 includes a socket 62 into which is inserted a ball 64 to form a ball and socket joint. The ball 64 includes pins 65A and 65B that fit into slots 67A and 67B in the socket 62, resulting in restricted motion of the ball and socket joint. The ball also includes a protrusion 66 having a plug 68. The connector 60 also includes a plate 70 that screws onto the back of the display with screws (not shown) that are inserted into the pairs of holes 71A-D. The plate 70 has a central opening 72 into which the protrusion 66 is inserted. The socket 62 mates with the periphery 74 of the opening 72. The socket 62 is screwed to the plate 70 with screws 76A, 76B, washers 77A, 77B and nuts 78A, 78B.

The plug 68 of the protrusion 66 mates with a complimentary-shaped portion of the stations 28, 30, 32, 34 and 36 in the extensions receptor 18 and extensions 20, 24. In particular, the station 34, for example, includes a cavity 79 that allows the plug 68 to slide therealong to allow the display 38 to be moved horizontally. (Stations 28, 32 and 36 likewise allow horizontal translation of the display, while station 30 allows vertical translation.) The cavity 79 includes an aperture 80 that extends from the front to the back of the extension 20. A bolt 82, with the use of two washers 83A, 83B, can be inserted from the back of the extension 20, through the aperture 80 and to the plug 68, which has a threaded hole 84 to accept the bolt 82. The bolt 82 can be tightened to secure the display to the extension 20. The bolt 82 can also be easily unscrewed to remove the display from the extension 20. Similar considerations apply to the other stations in the extensions receptor 18 or second extension 24.

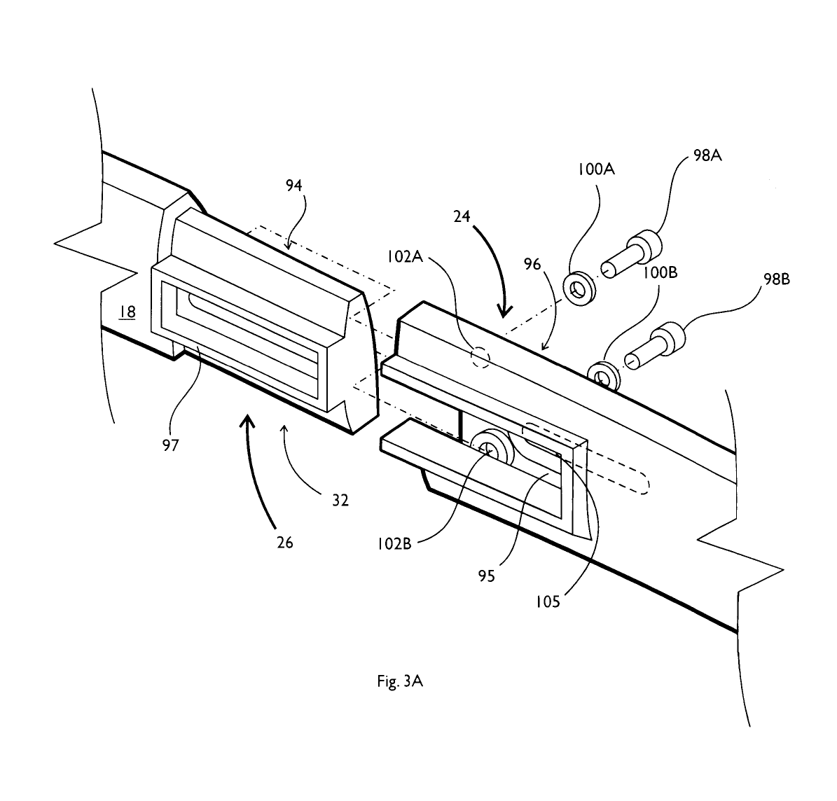

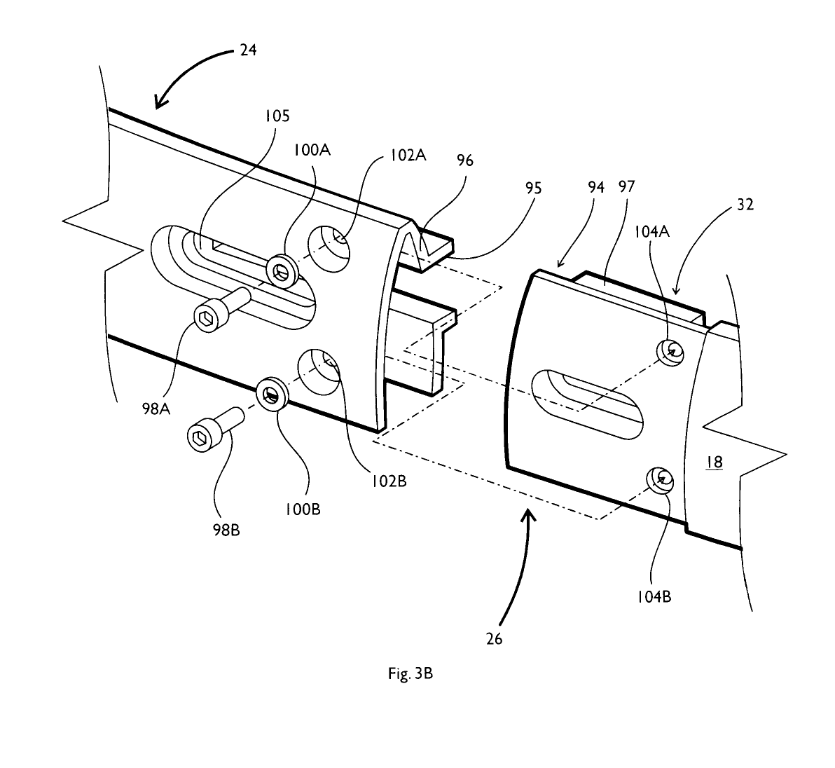

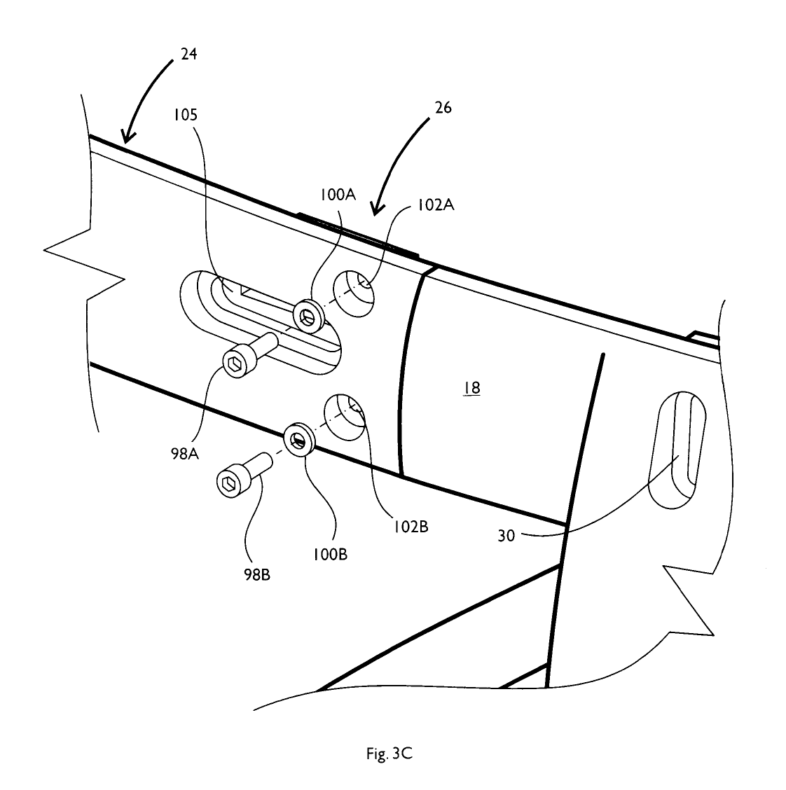

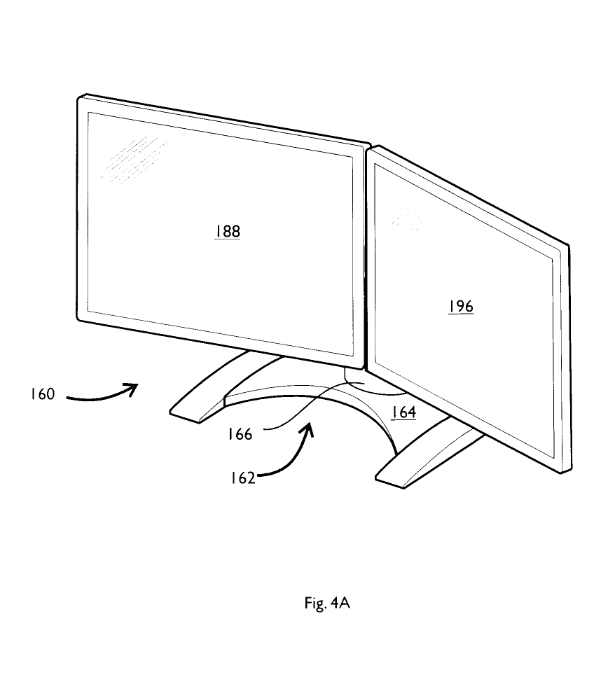

FIGS. 3A-C show an exploded front view, an exploded back view and an assembled back view of the station 32 near the end 26 of the extensions receptor 18 and the portion of the second extension 24 that connects thereto. A first mounting component 94 at one end 26 of the extensions receptor 18 mates with a second mounting component 96 at one end of the extension 24. In the embodiment shown, the first mounting component 94 is a male member and the second mounting component 96 is a female member, but it should be understood that instead the male member could be on the extension and the female member on the extensions receptor if desired. The second mounting component 96 slidingly engages with the first mounting component 94 to add the extension 24 to the extensions receptor 18. A groove 95 guides a corresponding projection 97 on the first mounting component 94 to facilitate the engagement.

Screws 98A and 98B and corresponding washers 100A and 100B are used to fasten the extension 24 to the extensions receptor 18. In particular, the screws 98A, 98B are inserted at the back of the extension 24 through holes 102A and 102 B and are screwed into threaded holes 104A and 104B in the extensions receptor 18. The screws 98A, 98B can be easily unscrewed to remove the extension 24. Similar considerations apply to the other extension 20.

Each extension 20 and 24 has two apertures. One aperture on the extension 24 is analogous to the aperture 80, and lies near the outer end of the extension 24. The other aperture is an inner aperture 105 (shown in FIGS. 3B and 3C) on the extension 24, which is near an opposite end of the extension 24. The aperture 105 allows a bolt (not shown), which is similar to the bolt 82 in FIGS. 2A and 2B, to be inserted therethrough to fasten the connector 53. Similar considerations apply to the other extension 20.

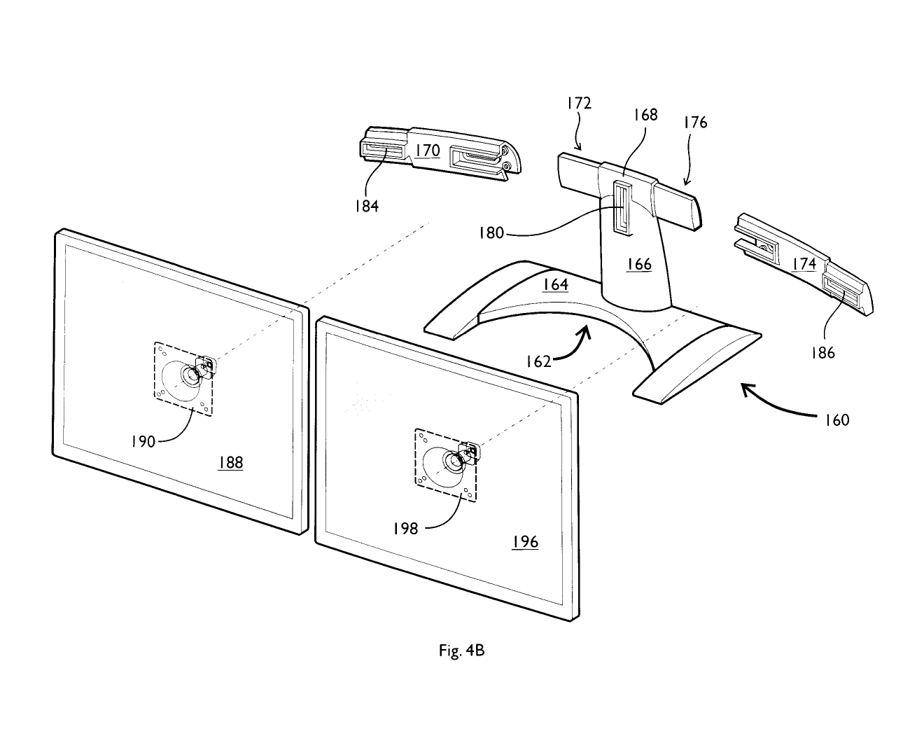

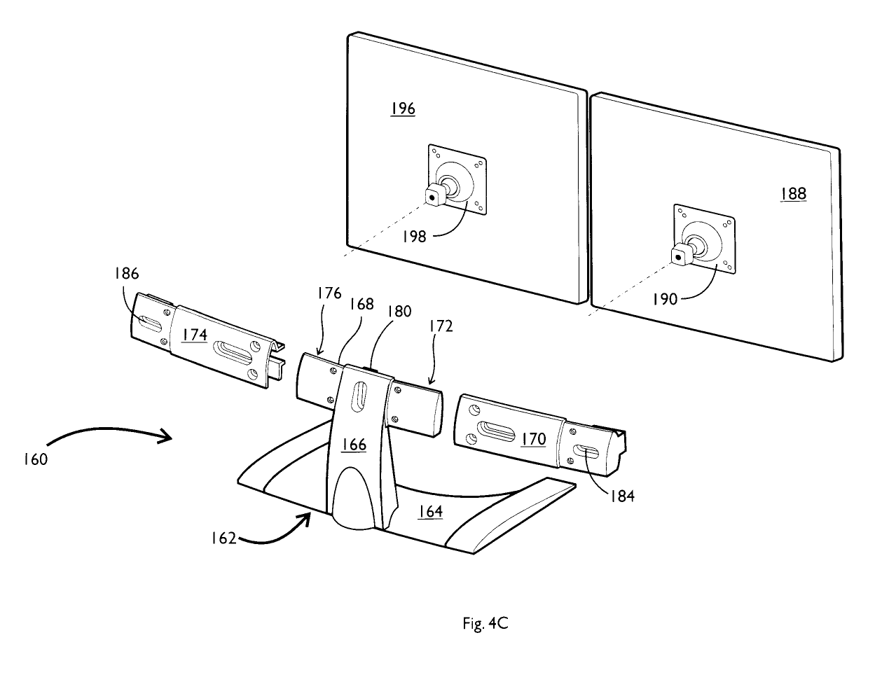

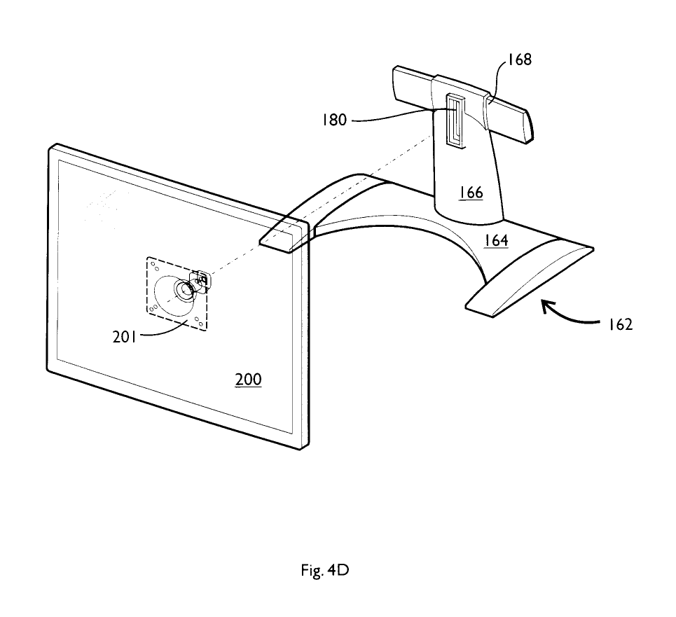

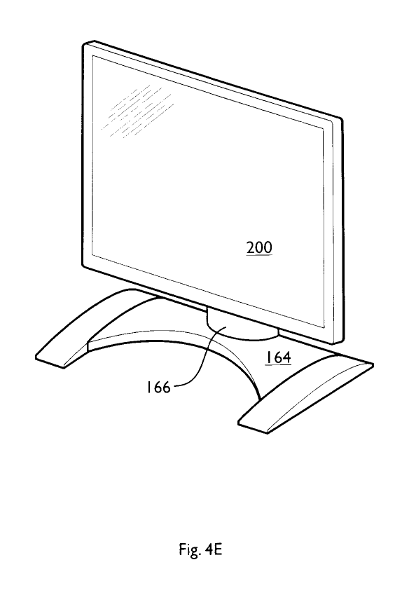

FIGS. 4A-E show another embodiment of a multi-display stand where M=1 and N=2. A multi-display stand 160 having a base structure 162, which structure 162 includes a base 164, a support column 166 and an extensions receptor 168. The multi-display stand 160 also includes a first extension 170 removably connected to one end 172 of the extensions receptor 168 and a second extension 174 removably connected to an opposite end 176 of the extensions receptor 168.

The extensions receptor 168 includes a central station 180. The first extension 170 includes a first extension station 184 and the second extension 174 includes a second extension station 186.

The back of a first outer display 188 has a first outer connector 190 and the back of a second outer display 196 has a second outer connector 198. The connector 190 mates with the first extension station 184, and the connector 198 mates with the second extension station 186. In this manner, the first extension 170 can support the first outer display 192 and the second extension 174 can support the second outer display 196. The connectors 190 and 198 are also capable of mating with some or all of the other stations 180, 184 and 186.

Each of the connectors 190 and 198 can be disconnected from the station mated therewith. FIG. 4B and FIG. 4C show a front and rear view respectively of the multi-display stand 160, with the two displays 188 and 196 disconnected therefrom, and the two extensions 170 and 174 disconnected from the extensions receptor 168.

The first extension 170 is removably connected to the end 172 of the extensions receptor 168, and the second extension 174 is removably connected to the end 176 of the extensions receptor 168. FIG. 4B and FIG. 4C show a front and rear view of the multi-display stand 160 with the first extension 170 and the second extension 174 disconnected from the extensions receptor 168. By removing the two extensions 170 and 174, the extensions receptor 168 is allowed to support a display 200, which has a connector 201 (similar to connector 40 in FIGS. 2A, 2B and 2D) at the back. It should be understood that the display 200 can be chosen from among the first outer display 188 and the second outer display 196 provided the connectors at the back of the displays can mate with the appropriate stations on the extensions receptor 168.

In FIG. 4D, a portion of the multi-display stand 160 is shown with the extensions 170 and 174 absent to illustrate how the display 200 mates with the central station 180. FIG. 4E shows the display 200 being supported by the extensions receptor 168.

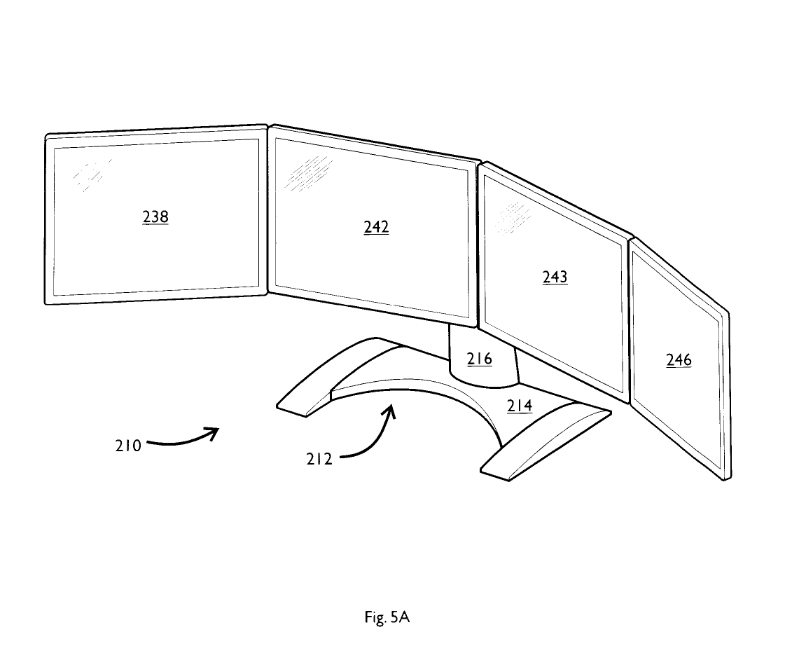

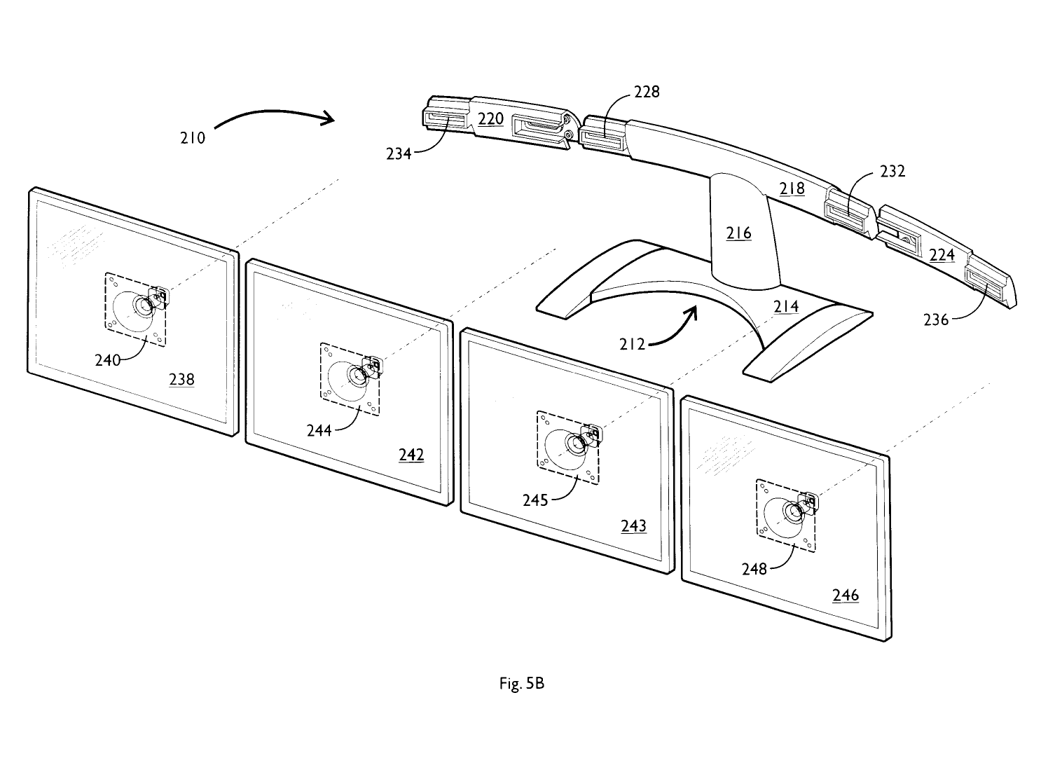

FIGS. 5A-E show another embodiment of a multi-display stand where M=2 and N=4. A multi-display stand 210 having a base structure 212, which structure 212 includes a base 214, a support column 216 and an extensions receptor 218. In the embodiment of FIGS. 5A-E, the extensions receptor 218 includes an arm extending from either side of the support column 216. The multi-display stand 210 also includes a first extension 220 removably connected to one end 222 of the extensions receptor 218 and a second extension 224 removably connected to an opposite end 226 of the extensions receptor 218.

The extensions receptor 218 includes a first outer station 228 and a second outer station 232. The first extension 220 includes a first extension station 234 and the second extension 224 includes a second extension station 236.

The back of a first outer display 238 has a first outer connector 240, the back of a first inner display 242 has a first inner connector 244, the back of a second inner display 243 has a second inner connector 245 and the back of a second outer display 246 has a second outer connector 248. The connector 240 mates with the first extension station 234, the connector 244 mates with the first outer station 228, the connector 245 mates with the second outer station 232 and the connector 248 mates with the second extension station 236. In this manner, the extensions receptor 218 can support the first and second inner displays 242, 243, the first extension 220 can support the first outer display 238 and the second extension 224 can support the second outer display 246. The connectors 240, 244, 245 and 248 are also capable of mating with some or all of the other stations 228, 232, 234 and 236.

Each of the connectors 240, 244, 245 and 248 can be disconnected from the station mated therewith. FIG. 5B and FIG. 5C show a front and rear view respectively of the multi-display stand 210, with the three displays 238, 242, 243 and 246 disconnected therefrom, and the extensions 220 and 224 disconnected from the extensions receptor 218.

The first extension 220 is removably connected to the end 222 of the extensions receptor 218, and the second extension 224 is removably connected to the end 226 of the extensions receptor 218. By removing the two extensions 220 and 224, the extensions receptor 218 is allowed to support two displays 250 and 252, which have connectors 251 and 253 (similar to connector 40 in FIGS. 2A, 2B and 2D) at their respective backs. It should be understood that the two displays 250 and 252 can be chosen from among the first outer display 238, the first inner display 242, the second inner display 243 and the second outer display 246 provided the connectors at the back of the displays can mate with the appropriate stations on the extensions receptor 218.

In FIG. 5D, a portion of the multi-display stand 210 is shown with the extensions 220 and 224 absent to illustrate how the two displays 250 and 252 mate with the first outer station 228 and the second outer station 232. FIG. 5E shows the two displays 250 and 252 being supported by the extensions receptor 218.

In the embodiment described above, the multi-display stand 210 conveniently allows a four-display system (FIGS. 5A-C) to be converted into a two-display system (FIGS. 5D-E). In particular, the display stand 210 can support four displays 238, 242, 243 and 246 when the extensions 220 and 224 are attached to the extensions receptor 218, and can support two displays 250 and 252 on the extensions receptor 218 when the extensions 220 and 224 are removed therefrom.

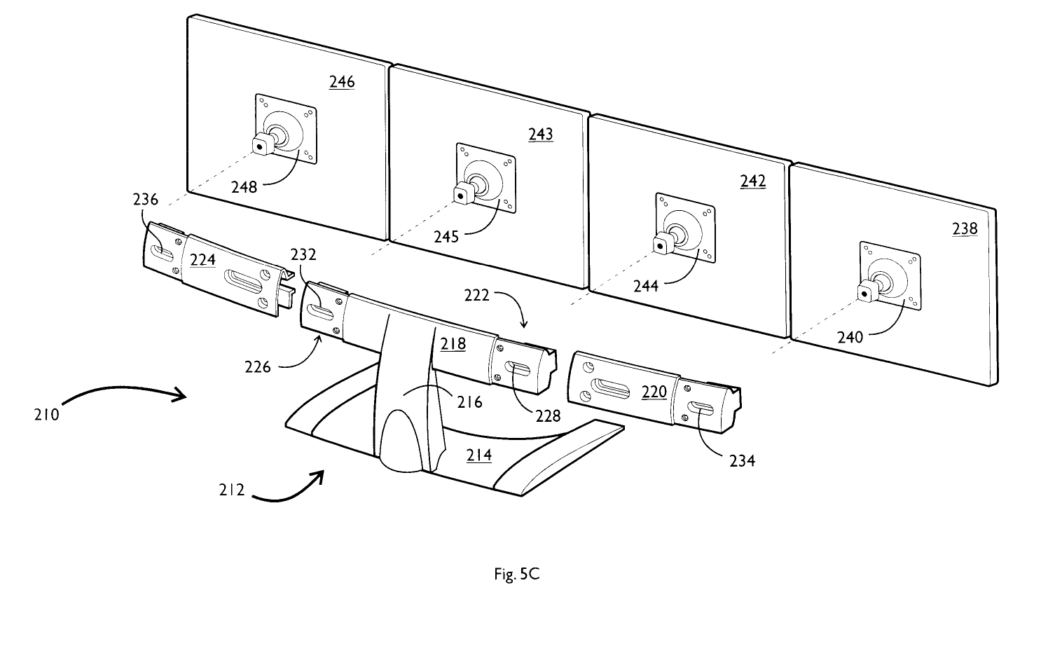

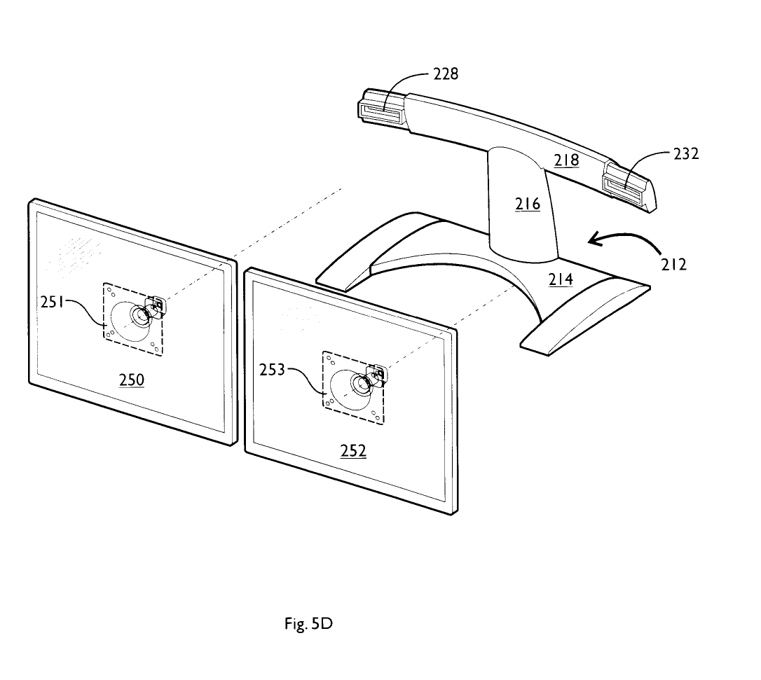

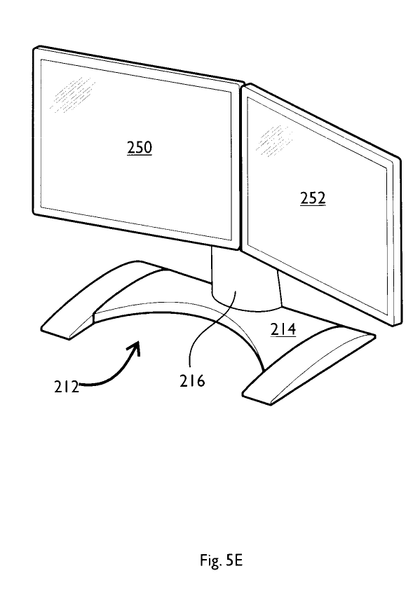

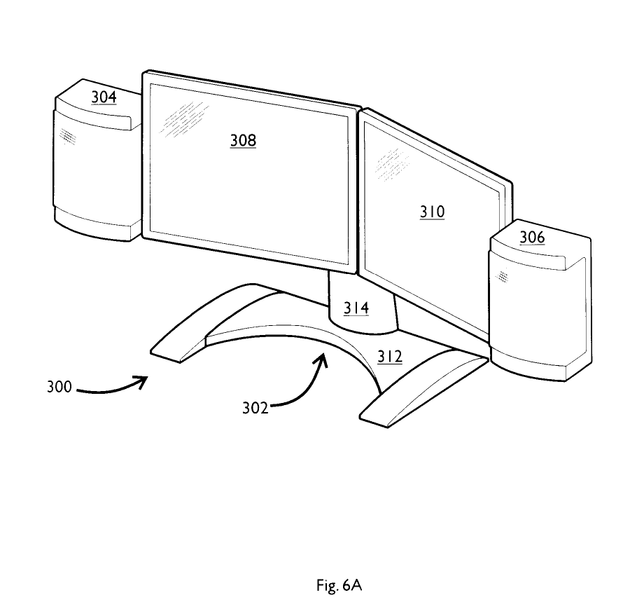

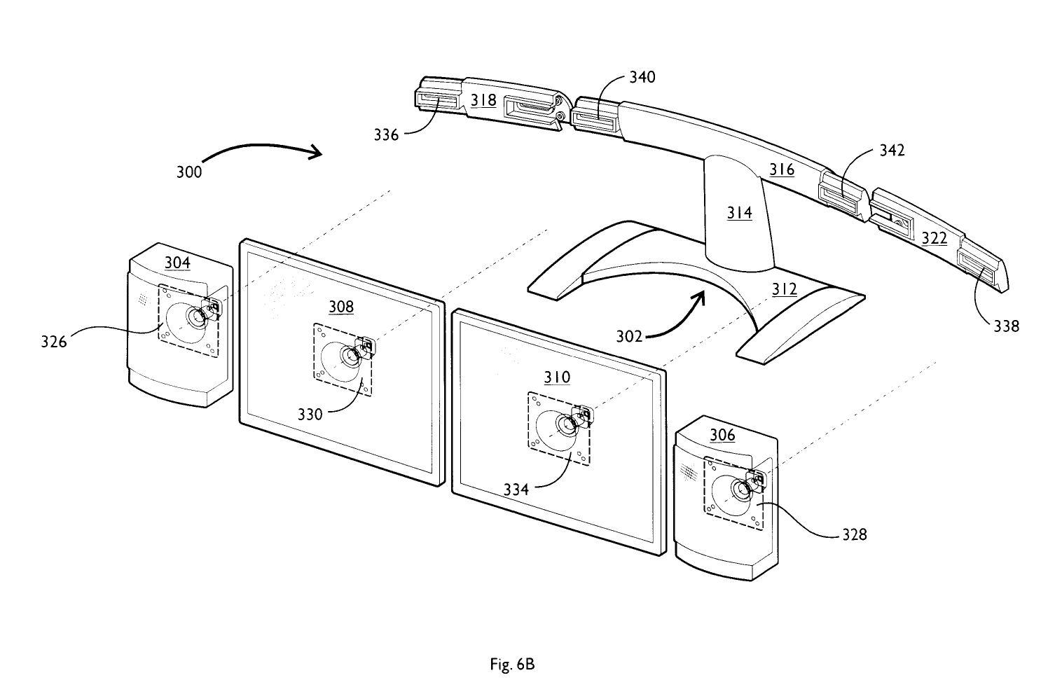

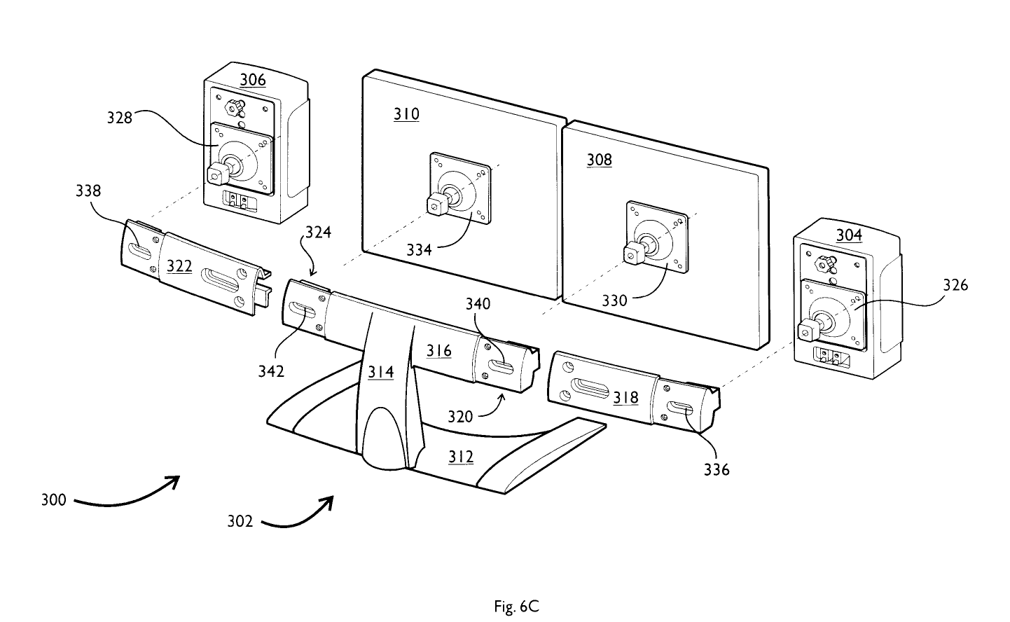

The scope of the foregoing can be broadened to include not just displays but other electronic devices capable of being supported by a stand. Referring to FIGS. 6A-6C, a multi-device stand 300 is shown that includes a base structure 302 for supporting four electronic devices, two outer speakers 304, 306 and two inner displays 308, 310. FIG. 6A is a front assembled view, FIG. 6B is a front unassembled view and FIG. 6C is a back unassembled view of the multi-device stand 300. The base structure 302 has a base 312, a support column 314 connected to the base 312, and an extensions receptor 316 connected to the support column 314. A first extension 318 is removably connected to one end 320 of the extensions receptor 316, and a second extension 322 is removably connected to another end 324 of the extensions receptor 316, such that the first extension 318, the extensions receptor 316 and the second extension 322 together can support the four electronic devices 304, 306, 308 and 310. The first and second extensions 318 and 322 can be removed to leave just two electronic devices 308 and 310 (the two inner displays) on the extensions receptor 316, such as in FIG. 1E.

The back of the first speaker 304 has a first speaker connector 326, and the back of the second speaker 306 has a second speaker connector 328. The back of the first display 308 has a first display connector 330, and the back of the second display 310 has a second display connector 334. The connector 326 mates with a first extension station 336, the connector 328 mates with a second extension station 338, the connector 330 mates with a first receptor station 340 and the connector 334 mates with a second receptor station 342. In this manner, the extensions receptor 316 can support the first and second displays 308, 310, the first extension 318 can support the first speaker 304 and the second extension 322 can support the second speaker 306. The connectors 326, 328, 330 and 334 are also capable of mating with some or all of the other stations 336, 338, 340 and 342. This allows the order of the speakers and displays to be changed. For example, the speakers can be disposed between the two displays.

The structure of the extensions receptor 316 and of the connectors 326, 328, 330, 334 and their corresponding stations 336, 338, 340 and 342 are similar to those described above in other embodiments, and will therefore not be described again.

Conveniently, the stand 300 is a modular system that can support two speakers 304, 306 and two displays 308, 310, and when the extensions are removed, can support the two displays 308, 310.

More generally, according to the principles of the present invention, a multi-device stand supports N electronic devices, where N is an integer greater than or equal to two, and where an electronic device can include a display or a peripheral device, such as a speaker or printer, for example. A first extension, removably connected to one end of an extensions receptor, supports at least one electronic device from among the N electronic devices. Likewise, a second extension, removably connected to another end of the extensions receptor, supports at least one other electronic device from among the N electronic devices. The first extension and the second extension can be removed to allow the extensions receptor to support M electronic devices, where M is an integer greater than zero and less than N. In the embodiment of FIGS. 6A and 6B, N=4 (two outer speakers and two inner displays) and M=2 (two inner displays).

It will be apparent to one of ordinary skill in the art to make changes to the foregoing embodiments while not departing from the scope of the present invention. For example, in FIGS. 1A-6C, the base is designed for resting on a horizontal surface and the support column is disposed substantially horizontally above the base. However, in other embodiments these characteristics need not be present. For example, the base can be designed to affix to a vertical wall or a ceiling with clamps or screws. The column extends from the base but not necessarily vertically. When affixed to a slat wall, for instance, the base can include a clamp and the support column can extend therefrom substantially horizontally.

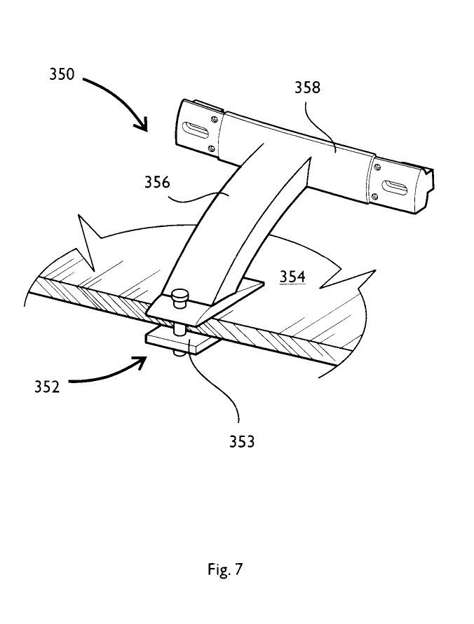

An example of a base structure 350 having a base 352 that includes a clamp 353 for attaching to the edge of a desk 354 is shown in FIG. 7. The base structure 350 includes a support column 356 and an extensions receptor 358 to which extensions and displays (neither is shown) can be attached, as described above.

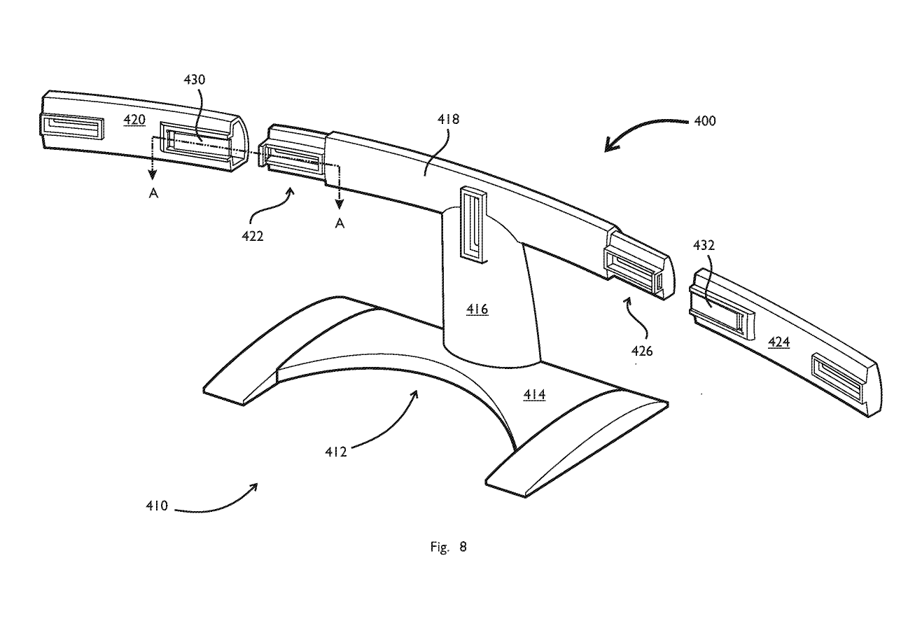

Referring to FIG. 8, another system 400 is shown representing another embodiment of the invention that requires no tools or bolts to removably connect the extensions to the extensions receptor.

The system 400 includes a multi-display stand 410 having a base structure 412, which structure 412 includes a base 414, a support column 416 connected to the base 414, and an extensions receptor 418 connected to the support column 416. The multi-display stand 410 also includes a first extension 420 removably connected to one end 422 of the extensions receptor 418 and a second extension 424 removably connected to an opposite end 426 of the extensions receptor 418.

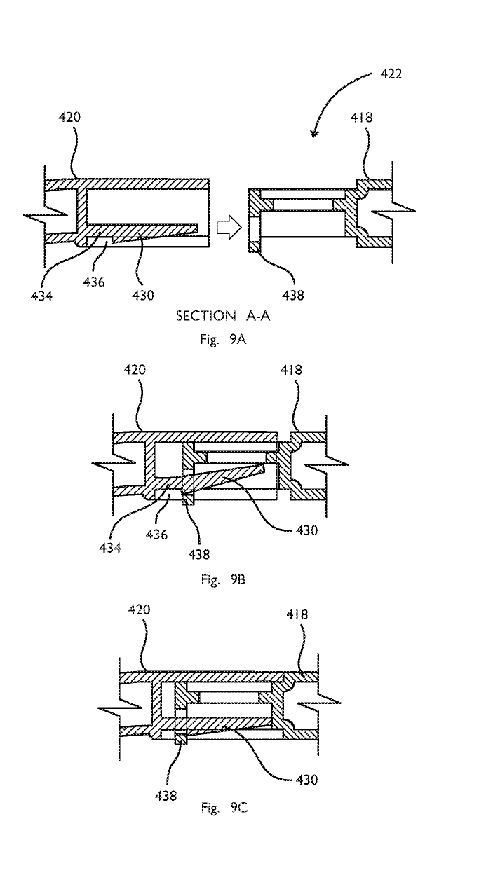

In the embodiment shown in FIG. 8, the first extension 420 and the second extension 424 snap onto the extensions receptor 418 without the need of tools or bolts. To achieve such a connection, and with reference to FIG. 9A-C, a first displaceable member 430 is provided as part of the first extension. A second displaceable member 432 is also provided as part of the second extension. The first displaceable member 430 and its function will now be described; it should be understood that a similar description applies to the second displaceable member 432.

FIG. 9A shows the cross section A-A of FIG. 8. In FIG. 9A, the first member 430 is shown in its equilibrium position. The first member 430 can be displaced or deflected, as shown in FIG. 9B, when a force is applied thereto whose direction is perpendicular to the first member 430 and in the plane of the FIG. 9A. A restoring member 434 exerts a restoring force on the member 430 when the member 430 is displaced. The restoring force tends to restore the member 430 to its equilibrium position.

The first member 430 is wedge-shaped, as shown in FIGS. 9A-C. Moreover, a notch 436 is provided near the junction of the restoring member 430 and the displaceable member 430. The extensions receptor 418 is provided with a displacing member 438 near the one end 422 that can mate with the notch 436, as shown in FIG. 9C.

To connect the first extension 420 to the extension receptor 418, the first member 430 is inserted into the one end 422 of the extensions receptor 418, facilitated by the wedge-shape of the displaceable member 430. As the first extension 420 is being inserted into the extensions receptor 418, the displacing member 438 displaces or deflects the member 430. As a result, the restoring member 434 exerts a force on the displaceable member 430 tending to restore the member 430 to its equilibrium position. When the first extension 420 is sufficiently inserted, the displaceable member 430, under the influence of the restoring force of the restoring member 434, returns towards its equilibrium position, allowing the displacing member 438 to mate with the notch 436. When the displacing member 438 and the notch 436 have mated, the first extension 420 is locked to the extensions receptor 418.

To remove the first extension 420 from the extension receptor 418, the member 430 can be depressed with a finger to clear the displacing member 438 from the notch 436 at the same time that an outward force is applied to the first extension 420, thereby separating the extension 420 from the extensions receptor 418.

More generally, one of the first extension and the extensions receptor includes a first displaceable member having an equilibrium position. The other of the first extension and the extensions receptor includes a first displacing member that displaces the first displaceable member when the first extension and the extensions receptor are being connected. When displaced, the first displaceable member experiences a force that tends to return the first displaceable member to the equilibrium position thereof causing the first extension to secure to the extensions receptor. To release the first extension from the extensions receptor, the first displaceable member is depressed.

Likewise, one of the second extension and the extensions receptor includes a second displaceable member having an equilibrium position. The other of the second extension and the extensions receptor includes a second displacing member that displaces the second displaceable member when the second extension and the extensions receptor are being connected. When displaced, the second displaceable member experiences a force that tends to return the second displaceable member to the equilibrium position thereof causing the second extension to secure to the extensions receptor. To release the second extension from the extensions receptor, the second displaceable member is depressed.

The foregoing embodiments are exemplary only, and are not meant to limit the scope of the invention. For example, the figures have shown various mating pairs. While certain male members of the mating pairs have been shown to reside in one of the extension or the extensions receptor, and the female members have been shown to reside in the other of the extension and the extensions receptor, it should be understood that, where appropriate, the position of the male and female members can be interchanged. For instance, instead of disposing the notch 436 in the extension 420 and the displacing member 438 in the extensions receptor 418, the notch can be disposed in the extensions receptor and the displacing member can be disposed in the extension. The scope of the invention is defined by the following claims.

What is claimed is:

1. A multi-display stand comprising:
a base structure for supporting three displays, the base structure having
a base,
a support column connected to the base, and
an extensions receptor connected to the support column;
a first extension removably connected to one end of the extensions receptor, wherein one of the first extension and the extensions receptor includes a first displaceable member having an equilibrium position, and the other one of the first extension and the extensions receptor includes a first displacing member that displaces the first displaceable member when the first extension and the extensions receptor are being connected, the first displaceable member experiencing a first force when displaced that tends to return the first displaceable member to the equilibrium position thereof causing the first extension to secure to the extensions receptor; and
a second extension removably connected to another end of the extensions receptor, wherein one of the second extension and the extensions receptor includes a second displaceable member having an equilibrium position, and the other one of the second extension and the extensions receptor includes a second displacing member that displaces the second displaceable member when the second extension and the extensions receptor are being connected, the second displaceable member experiencing a second force when displaced that tends to return the second displaceable member to the equilibrium position thereof causing the second extension to secure to the extensions receptor, such that the first extension, the extensions receptor and the second extension together can support three displays, wherein a) the first extension supports at least one display from among the three displays and the second extension supports at least one other display from among the three displays, and b) the first extension and the second extension can be removed to allow the extensions receptor to support two displays.

2. The multi-display stand of claim 1, wherein a) the extensions receptor includes an arm extending from either side of the support column, and b) the extensions receptor includes a first outer station, a central station and a second outer station opposite the first outer station, each station designed to mate with a display connector for connecting a display to the extensions receptor when the first extension and the second extension are removed from the extensions receptor.

3. The multi-display stand of claim 2, wherein the first extension includes a first extension station designed to mate with a display connector for connecting a display to the first extension, and wherein the second extension includes a second extension station designed to mate with a display connector for connecting a display to the second extension.

4. The multi-display stand of claim 3, wherein a) concomitantly, the first extension can accommodate a first display connected to the first extension station via a display connector, the extensions receptor can accommodate a second display connected to the central station via a display connector, and the second extension can accommodate a third display connected to the second extension station via a display connector, and b) when the first and second extensions are removed, the extensions receptor can accommodate concomitantly:
a display, selected from the group consisting of the first display, the second display and the third display, connected to the first outer station via a display connector, and
another display, selected from the group consisting of the first display, the second display and the third display, connected to the second outer station via a display connector.

5. The multi-display stand of claim 1, wherein a) the first extension supports at least one display, at the rear thereof, from among the three displays and the second extension supports at least one other display, at the rear thereof, from among the three displays, and b) the first extension and the second extension can be removed to allow the extensions receptor to support two displays, at the rears thereof.

6. The multi-display stand of claim 5, wherein the base is wider than the column and narrower than the combined length of the extensions receptor, the first extension and the second extension, as determined when the first and second extensions are connected to the extensions receptor.

7. The multi-display stand of claim 6, wherein the base is adapted to rest on a horizontal surface.

8. The multi-display stand of claim 1, further comprising:
a first restoring member connected to the first displaceable member for partially or wholly exerting the first force on the first displaceable member; and
a first notch disposed proximal to where the first restoring member is connected to the first displaceable member, the first displacing member capable of mating with the first notch, wherein to connect the first extension to the extension receptor, the first extension is inserted into the one end of the extensions receptor so as to insert the first displaceable member therein, such that when the first extension is sufficiently inserted, the first displaceable member, under the influence of the first force, returns towards its equilibrium position, allowing the first displacing member to mate with the first notch, and thereby causing the first extension to secure to the extensions receptor.

9. The multi-display stand of claim 28, wherein the first displaceable member is wedge-shaped.

10. The multi-display stand of claim 9, such that the first displaceable member is displaced to the greatest extent at an end opposite the first restoring member.

11. The multi-display stand of claim 10, wherein the second displaceable member is wedge-shaped.

12. The multi-display stand of claim 11, such that the second displaceable member is displaced to the greatest extent at an end opposite the first restoring member.
